(19) United States
(12) Patent Application Publication
(10) Pub. No.: US 2011/0198027 A1
(43) Pub. Date: Aug. 18, 2011

(54) METHOD FOR MANUFACTURING SILICON CARBIDE SUBSTRATE

(75) Inventors: Taro NISHIGUCHI, Itami-shi (JP); Makoto SASAKI, Itami-shi (JP); Shin HARADA, Osaka-shi (JP); Kyoko OKITA, Itami-shi (JP); Hiroki INOUE, Itami-shi (JP); Yasuo NAMIKAWA, Itami-shi (JP)

(73) Assignee: Sumitomo Electric Industries, Ltd., Osaka-shi (JP)

(21) Appl. No.: 13/025,879

(22) Filed: Feb. 11, 2011

(30) Foreign Application Priority Data
Feb. 12, 2010 (JP) 2010-029144

(51) Int. Cl. C09J 5/10

(52) U.S. Cl. 156/306.6

(57) ABSTRACT

A base portion and first and second silicon carbide substrates are disposed in a processing chamber such that a first side surface of a first silicon carbide substrate and a side surface of a second silicon carbide substrate face each other. The processing chamber has an inner surface at least a portion of which is covered with an absorbing portion including Ta atoms and C atoms. In order to connect the first and second side surfaces to each other, a temperature in the processing chamber is increased to reach or exceed a temperature at which silicon carbide can sublime. In the step of increasing the temperature, at least a portion of the absorbing portion is carbonized.

### BACKGROUND OF THE INVENTION

1. Field of the Invention

The present invention relates to a method for manufacturing a silicon carbide substrate.

2. Description of the Background Art

In recent years, SiC substrates have been adopted as semiconductor substrates for use in manufacturing semiconductor devices. SiC has a band gap larger than that of Si (silicon), which has been used more commonly. Hence, a semiconductor device employing a SiC substrate advantageously has a large reverse breakdown voltage, low on-resistance, and properties less likely to decrease in a high temperature environment.

In order to efficiently manufacture such semiconductor devices, the substrates need to be large in size to some extent. According to U.S. Pat. No. 7,314,520, a SiC substrate of 76 mm (3 inches) or greater can be manufactured.

Industrially, the size of a SiC substrate is still limited to approximately 100 mm (4 inches). Accordingly, semiconductor devices cannot be efficiently manufactured using large substrates, disadvantageously. This disadvantage becomes particularly serious in the case of using a property of a plane other than the (0001) plane in SiC of hexagonal system. Hereinafter, this will be described.

A SiC substrate small in defect is usually manufactured by slicing a SiC ingot obtained by growth in the (0001) plane, which is less likely to cause stacking fault. Hence, a SiC substrate having a plane orientation other than the (0001) plane is obtained by slicing the ingot not in parallel with its grown surface. This makes it difficult to sufficiently secure the size of the substrate, or many portions in the ingot cannot be used effectively. For this reason, it is particularly difficult to effectively manufacture a semiconductor device that employs a plane other than the (0001) plane of SiC.

Instead of increasing the size of such a SiC substrate with difficulty, it is considered to use a silicon carbide substrate having a base portion and a plurality of small single-crystal substrates disposed thereon. The size of this semiconductor substrate can be increased by increasing the number of single-crystal substrates as required.

However, in this silicon carbide substrate, spaces are formed between adjacent single-crystal substrates. In the spaces, foreign matters are likely to be accumulated during a process of manufacturing a semiconductor device using the silicon carbide substrate. An exemplary foreign matter is: a cleaning liquid or polishing agent used in the process of manufacturing a semiconductor device; or dust in the atmosphere. Such foreign matters result in decreased manufacturing yield, which leads to decreased efficiency of manufacturing semiconductor devices, disadvantageously.

### SUMMARY OF THE INVENTION

The present invention is made in view of the foregoing problems and its object is to provide a method for manufacturing a large silicon carbide substrate allowing for manufacturing of semiconductor devices with a high yield.

A method for manufacturing a silicon carbide substrate in the present invention includes the following steps.

A base portion formed of silicon carbide is prepared. First and second single-crystal substrates each formed of silicon carbide are prepared. The first single-crystal substrate has a first backside surface, a first front-side surface opposite to the first backside surface, and a first side surface connecting the first backside surface and the first front-side surface to each other. The second single-crystal substrate has a second backside surface, a second front-side surface opposite to the second backside surface, and a second side surface connecting the second backside surface and the second front-side surface to each other. A processing chamber is prepared. The processing chamber has an inner surface at least a portion of which is covered with an absorbing portion including Ta atoms and C atoms. The base portion and the first and second single-crystal substrates are disposed in the processing chamber such that each of the first and second backside surfaces faces the base portion and the first and second side surfaces face each other. A temperature in the processing chamber is increased to reach or exceed a temperature at which silicon carbide is able to sublime, so as to connect the first and second side surfaces to each other. In the step of increasing the temperature, at least a portion of the absorbing portion is carbonized.

According to this manufacturing method, the first and second side surfaces are connected to each other, thereby filling a space between the first and second single-crystal substrates. Accordingly, foreign matters are not accumulated in the space upon manufacturing semiconductor devices using the silicon carbide substrate. This prevents yield from being decreased by the foreign matters, thus obtaining a semiconductor substrate allowing for manufacturing of semiconductor devices with a high yield.

Further, in a heating step, the Ta atoms included in the absorbing portion absorb a part of C atoms in the atmosphere of the processing chamber, thereby preventing the concentration of C atoms from being too large in the atmosphere. This facilitates desorption of C atoms from the first and second side surfaces, whereby the first and second side surfaces are less likely to be carbonized. Accordingly, the first and second side surfaces can be connected to each other more securely. Further, since the absorbing portion is thus provided with C atoms in advance, abrupt occurrence of absorption of C atoms can be prevented when a new absorbing portion is started to be used.

Preferably, the absorbing portion has a first portion having Ta atoms at a concentration higher than that of C atoms. Accordingly, in the first portion, Ta atoms, which do not constitute TaC (tantalum carbide), can be provided to absorb C atoms.

Preferably, the absorbing portion has a second portion covering the first portion, and a ratio of concentration of Ta atoms to concentration of C atoms in the second portion is smaller than a ratio of the concentration of the Ta atoms to the concentration of the C atoms in the first portion. Thus, the second portion allows C atoms to be gradually absorbed into the first portion having the high concentration ratio of Ta atoms. Hence, even when a relatively new absorbing portion is started to be used, occurrence of abrupt absorption of C atoms can be prevented.

Preferably, in the step of increasing the temperature, each of the first and second single-crystal substrates is set to have a temperature lower than that of the base portion. Accordingly, voids formed between the base portion and each of the first and second single-crystal substrates can be moved toward the base portion.

Preferably, in the step of increasing the temperature in the processing chamber, each of the first and second backside surfaces and the base portion are connected to each other. Thus, each of the first and second single-crystal substrates and the base portion can be connected to each other at the same time as the connecting of the first and second side surfaces.

Preferably, the step of disposing the base portion and the first and second single-crystal substrates includes a step of placing the first and second single-crystal substrates on the base portion. In this way, the first and second single-crystal substrates can be disposed readily.

Preferably, at least a portion of the processing chamber is formed of graphite. In this way, a processing chamber with a high heat resistance can be formed readily.

As apparent from the description above, the present invention can provide a method for manufacturing a large silicon carbide substrate allowing for manufacturing semiconductor devices with a high yield.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a configuration of a silicon carbide substrate in a first embodiment of the present invention.

FIG. 2 is a schematic cross sectional view along a line II-II in FIG. 1.

FIG. 3 is a plan view schematically showing a first step in a method for manufacturing the silicon carbide substrate in the first embodiment of the present invention.

FIG. 4 is a schematic cross sectional view along a line IV-IV in FIG. 3.

FIG. 5 is a cross sectional view schematically showing a second step in the method for manufacturing the silicon carbide substrate in the first embodiment of the present invention.

FIG. 6 shows an exemplary profile for a ratio of the concentration of Ta atoms to the concentration of C atoms along an arrow X in FIG. 5.

FIG. 7 is a partial cross sectional view schematically showing a configuration of a semiconductor device in a second embodiment of the present invention.

FIG. 8 is a schematic flowchart of a method for manufacturing the semiconductor device in the second embodiment of the present invention.

Each of FIG. 9-FIG. 12 is a partial cross sectional view schematically showing first to fourth steps of the method for manufacturing the semiconductor device in the second embodiment of the present invention.

### DESCRIPTION OF THE PREFERRED EMBODIMENTS

The following describes embodiments of the present invention with reference to figures.

### First Embodiment

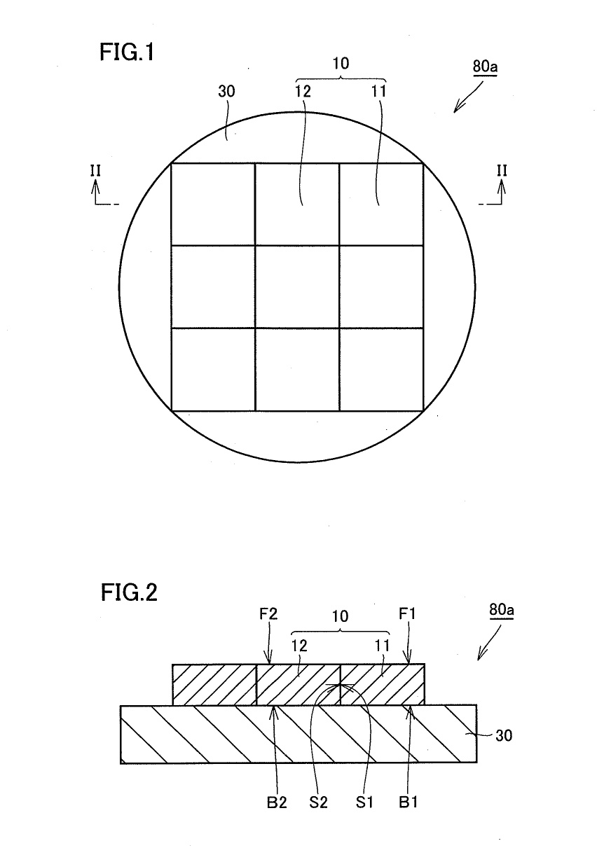

Referring to FIG. 1 and FIG. 2, a silicon carbide substrate 80a of the present embodiment has a base portion 30 and a substrate group 10 supported by base portion 30. Base portion 30 is formed of silicon carbide.

Substrate group 10 is constituted by a plurality of single-crystal substrates each formed of silicon carbide, and includes a SiC substrate 11 (first single-crystal substrate) and a SiC substrate 12 (second single-crystal substrate). SiC substrate 11 has a backside surface B1 (first backside surface) facing base portion 30, a front-side surface F1 (first front-side surface) opposite to backside surface B1, and a side surface S1 (first side surface) connecting backside surface B1 and front-side surface F1 to each other. SiC substrate 12 has a backside surface B2 (second backside surface) facing base portion 30, a front-side surface F2 (second front-side surface) opposite to the second backside surface, and a side surface S2 (second side surface) connecting backside surface B2 and front-side surface F2 to each other. Each of backside surfaces B1 and B2 is connected to one main surface of base portion 30. Side surfaces S1 and S2 face each other and are connected to each other.

Each one in substrate group 10 has a front-side surface exposed in the same flat plane. For example, SiC substrates 11 and 12 respectively have front-side surfaces F1 and F2 (FIG. 2). In this way, silicon carbide substrate 80a has a front-side surface larger than that of each one in substrate group 10. Hence, in the case of using silicon carbide substrate 80a, semiconductor devices can be manufactured more effectively than in the case of using each one in substrate group 10 solely.

It should be noted that substrate group 10 has a thickness of, for example, 300 μm. Further, for example, substrate group 10 has n type conductivity, and has an impurity concentration of 1×10¹⁹ cm⁻³. Further, base portion 30 has a thickness of, for example, 300 μm. Furthermore, for example, base portion 30 has n type conductivity, and has an impurity concentration of 1×10²⁰ cm⁻³.

The following describes a method for manufacturing silicon carbide substrate 80a. For ease of description, only SiC substrates 11 and 12 of the plurality of SiC substrates included in substrate group 10 may be explained, but the same explanation also applies to the other SiC substrates thereof.

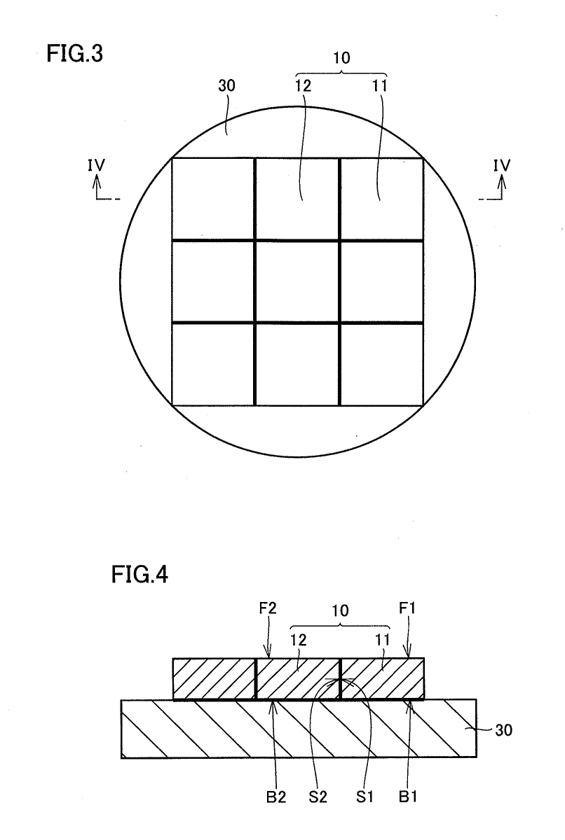

Referring to FIG. 3 and FIG. 4, SiC substrates 11, 12 and base portion 30 are prepared. Then, each of SiC substrates 11 and 12 is placed on base portion 30 so that each of backside surfaces B1 and B2 faces base portion 30 and side surfaces S1 and S2 face each other.

Referring to FIG. 5, a processing chamber 60 is prepared. Processing chamber 60 is formed of graphite. Further, processing chamber 60 has an inner surface at least a portion of which is coated by a coating 52 (absorbing portion). Preferably, this inner surface is entirely coated by coating 52. Preferably, coating 52 has a thickness of 1 μm or greater. Coating 52 includes Ta atoms and C atoms.

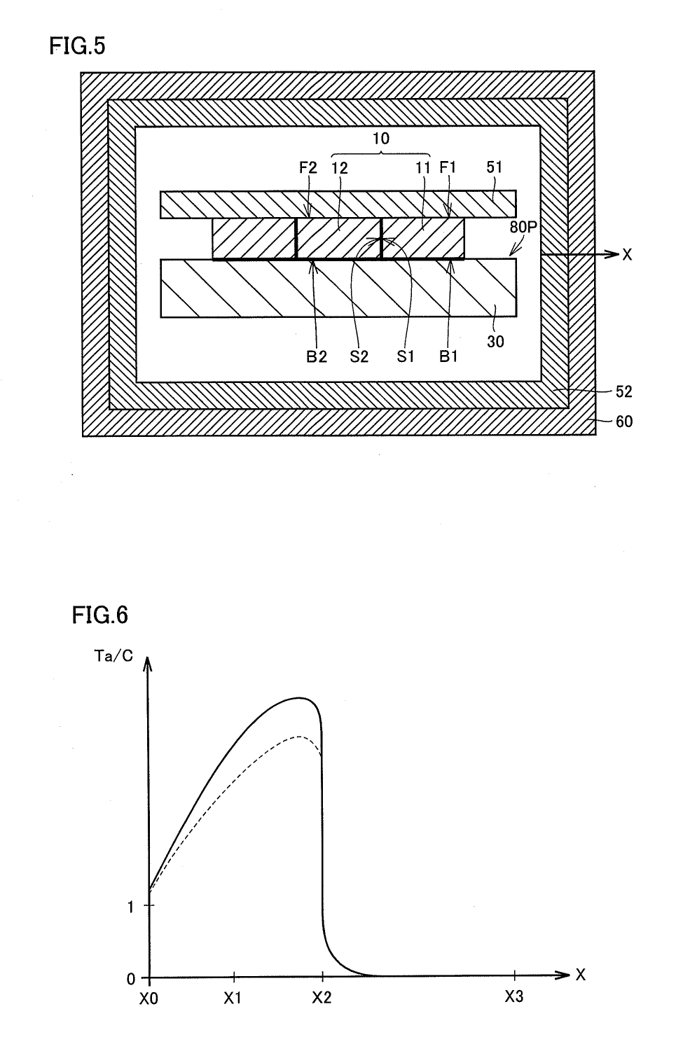

Referring to FIG. 6, there is shown a profile (FIG. 6) for a ratio of the concentration of Ta atoms to the concentration of C atoms (concentration ratio) along an axis X (FIG. 5). A location X0 corresponds to the inner surface, coated with coating 52, of processing chamber 60, i.e., a surface of coating 52. A location X1 corresponds to the inside of coating 52. A location X2 corresponds to an interface between coating 52 and processing chamber 60. A location X3 corresponds to an outer surface of processing chamber 60. As shown in this profile, coating 52 has a portion having a concentration ratio exceeding 1. In other words, coating 52 has a portion having Ta atoms at a higher concentration than the concentration of C atoms. In coating 52, a portion (second portion) near location X0 covers a portion (first portion) near location X1. The concentration ratio in location X0 is smaller than the concentration ratio in location X1.

As a method for forming coating 52 on the inner surface of processing chamber 60, for example, any one of the following first to third methods can be used. In the first method, CVD (Chemical Vapor Deposition) can be employed to form a dense coating 52. As the second method, there can be used a method of first forming a Ta film and diffusing C atoms from a surface of the Ta film into the inside of the Ta film. In this case, gradient of the concentration of C atoms can be readily provided in the thickness direction of coating 52. In the third method, a sputtering method can be employed to form coating 52 corresponding to the shape of the inner surface of processing chamber 60, even in the case where the inner surface has a complex shape.

Then, base portion 30 is brought into processing chamber 60. Specifically, base portion 30 and SiC substrates 11, 12 are disposed in processing chamber 60 such that each of backside surfaces B1 and B2 faces base portion 30 and side surfaces S1 and S2 face each other.

Next, a heating step is performed to increase the temperature in processing chamber 60 to reach or exceed a temperature at which silicon carbide can sublime. This heating step is preferably performed to allow each of the temperatures of SiC substrates 11 and 12 to be lower than the temperature of base portion 30.

This heating step causes sublimation of silicon carbide from surfaces in a space between side surfaces S1 and S2 on base portion 30. Specifically, in this space, molecular species of SiC₂, Si₂C, and Si are formed.

A part of C atoms included in the above-described SiC₂ and Si₂C react with coating 52 to carbonize at least a portion of coating 52. Accordingly, the concentration of C atoms in the atmosphere of processing chamber 60 is reduced, thereby reducing the concentration of C atoms in the atmosphere within the space between side surfaces S1 and S2 on base portion 30. This facilitates desorption of C atoms from the surfaces in the space between side surfaces S1 and S2 on base portion 30. Accordingly, the surfaces in the space between side surfaces S1 and S2 are less likely to be graphitized, thereby activating sublimation and resolidification reactions in this space. This facilitates connecting of side surfaces S1 and S2, thus filling the space therebetween.

Further, at the same time as the connecting of side surfaces S1 and S2, each of backside surfaces B1 and B2, and base portion 30 are connected to each other by means of the sublimation and resolidification reactions of silicon carbide. In this way, silicon carbide substrate 80a (FIG. 2) is obtained.

According to the present embodiment, side surfaces S1 and S2 are connected to each other to fill the space between SiC substrates 11 and 12. Accordingly, foreign matters are not accumulated in the space upon manufacturing a semiconductor device using silicon carbide substrate 80a. This can prevent yield from being decreased by the foreign matters, thereby obtaining a silicon carbide substrate that allows for manufacturing of semiconductor devices with a high yield.

In the heating step, the Ta atoms included in coating 52 absorb a part of the C atoms in processing chamber 60, thereby preventing existence of too many C atoms in processing chamber 60. This facilitates desorption of C atoms from side surfaces S1 and S2, whereby side surfaces S1 and S2 are less likely to be carbonized. Accordingly, side surfaces S1 and S2 can be connected to each other more securely. Further, since coating 52 is thus provided with C atoms in advance, abrupt occurrence of absorption of C atoms can be prevented when a new coating 52 is started to be used.

Further, as shown in FIG. 6, coating 52 has a portion having a concentration ratio exceeding 1, i.e., a portion having Ta atoms at a higher concentration than the concentration of C atoms. In this way, Ta atoms, which do not constitute TaC, are provided and can absorb C atoms.

Further, coating 52 has the portion located near location X0 and covering the portion located near location X1, and the concentration ratio in location X0 is smaller than that in location X1 as shown in FIG. 6. Accordingly, the portion near location X0 allows C atoms to be absorbed in the portion near location X1, gradually. Thus, when a new coating 52 is started to be used, C atoms are more securely prevented from being abruptly absorbed.

Further, coating 52 covers at least a portion of the inner surface of processing chamber 60, thus reducing an influence of the inner surface of processing chamber 60 over the atmosphere in processing chamber 60. In particular, in the case where processing chamber 60 is formed of graphite, increase in concentration of C atoms caused by the graphite can suppressed in the atmosphere of processing chamber 60.

Further, at the same time as the connecting of side surfaces S1 and S2, base portion 30 and each of backside surfaces B1 and B2 thereon are connected to each other. Namely, at the same time as the connecting of side surfaces S1 and S2, each of SiC substrates 11, 12 and base portion 30 can be connected to each other.

Further, in the heating step, the temperature of each of SiC substrates 11 and 12 is set lower than that of base portion 30, thereby allowing voids formed between base portion 30 and each of SiC substrates 11 and 12 to move toward base portion 30.

It should be noted that base portion 30 of silicon carbide substrate 80a preferably has an electric resistivity of 50 mΩ·cm or smaller, more preferably, 10 mΩ·cm or smaller.

Further, it is preferable to introduce a gas containing nitrogen into processing chamber 60, when increasing the temperature in processing chamber 60. Accordingly, the connecting of side surfaces S1 and S2 can be facilitated and nitrogen can be introduced into base portion 30 as an impurity.

Moreover, base portion 30 preferably has a circular shape. In this case, base portion 30 preferably has a diameter of 5 cm (2 inches) or greater, more preferably, 15 cm (6 inches) or greater. Further, upon the connecting to base portion 30, it is preferable to flatten the connecting surfaces, i.e., backside surfaces B1, B2 and the surface of base portion 30 that faces backside surfaces B1, B2. Moreover, variation in thickness between base portion 30 and each of SiC substrates 11, 12 is preferably approximately 10 μm or smaller. Further, silicon carbide substrate 80a preferably has a thickness of 300 μm or greater.

Furthermore, each of SiC substrates 11, 12 preferably has a crystal structure with a polytype of 4H, so as to obtain a silicon carbide substrate 80a more suitable for manufacturing power semiconductors. Moreover, each of SiC substrates 11, 12, and base portion 30 has the same crystal structure. Further, a difference in thermal expansion coefficient between each of SiC substrates 11, 12 and base portion 30 is preferably small enough to prevent cracks from being generated due to the difference in thermal expansion in the process of manufacturing semiconductor devices using silicon carbide substrate 80a.

Meanwhile, preferably, front-side surface F1 has an off angle of not less than 50° and not more than 65° relative to the {0001} plane of SiC substrate 11 and front-side surface F2 has an off angle of not less than 50° and not more than 65° relative to the {0001} plane of SiC substrate 12. This allows for higher channel mobility in each of front-side surfaces F1, F2 than in the case where each of the front-side surfaces F1, F2 corresponds to the {0001} plane.

More preferably, the off orientation of front-side surface F1 forms an angle of not more than 5° with the <1-100> direction of SiC substrate 11, and the off orientation of front-side surface F2 forms an angle of not more than 5° with the <1-100> direction of SiC substrate 12. This allows for higher channel mobility in each of front-side surfaces F1, F2.

Further, front-side surface F1 preferably has an off angle of not less than −3° and not more than 5° relative to the {03-38} plane in the <1-100> direction of SiC substrate 11, and front-side surface F2 preferably has an off angle of not less than −3° and not more than 5° relative to the {03-38} plane in the <1-100> direction of SiC substrate 12. This allows for further higher channel mobility in each of front-side surfaces F1, F2.

It should be noted that the “off angle of surface F1 relative to the {03-38} plane in the <1-100> direction” refers to an angle formed by an orthogonal projection of a normal line of front-side surface F1 to a projection plane defined by the <1-100> direction and the <0001> direction, and a normal line of the {03-38} plane. The sign of positive value corresponds to a case where the orthogonal projection approaches in parallel with the <1-100> direction whereas the sign of negative value corresponds to a case where the orthogonal projection approaches in parallel with the <0001> direction. This is similar in the “off angle of front-side surface F2 relative to the {03-38} plane in the <1-100> direction”.

Further, preferably, the off orientation of front-side surface F1 forms an angle of not more than 5° with the <11-20> direction of SiC substrate 11, and the off orientation of front-side surface F2 forms an angle of not more than 5° with the <11-20> direction of SiC substrate 12. This allows for higher channel mobility in each of front-side surfaces F1, F2 than in the case where each of the front-side surfaces F1, F2 corresponds to the {0001} plane.

Further, in the present embodiment, the connecting of side surfaces S1 and S2 and the connecting of each of backside surfaces B1 and B2 and the base portion are done at the same time. However, as a variation, each of SiC substrates 11, 12 and base portion 30 may be connected to each other in advance, and then side surfaces S1 and S2 may be connected to each other using a method similar to that in the present embodiment.

Further, as base portion 30, a substrate having more defects than in substrate group 10 can be used. For example, as each one in substrate group 10, there can be used a substrate having a micro pipe density of 0.2 cm⁻² and having a stacking fault density of less than 1 cm⁻¹, whereas as base portion 30, there can be used a substrate having a micro pipe density of 1×10⁴ cm⁻² and having a stacking fault density of 1×10⁵ cm⁻¹. Alternatively, base portion 30 may have a polycrystalline structure or may be a sintered compact.

Further, as described above, existence of defects is relatively permitted in base portion 30, so the impurity concentration of base portion 30 can be increased readily as compared with that of substrate group 10.

### Second Embodiment

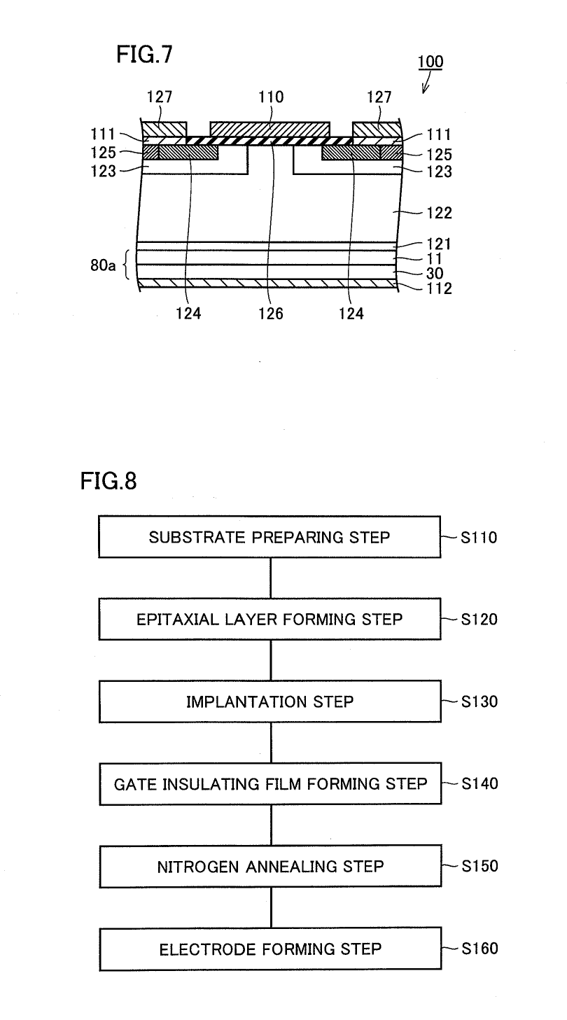

Referring to FIG. 7, a semiconductor device 100 of the present embodiment is a vertical type DiMOSFET (Double Implanted Metal Oxide Semiconductor Field Effect Transistor), and includes a silicon carbide substrate 80a, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112.

In the present embodiment, silicon carbide substrate 80a has n type conductivity, and has base portion 30 and SiC substrate 11 as described in the first embodiment. Drain electrode 112 is provided on base portion 30 to interpose base portion 30 between drain electrode 112 and SiC substrate 11. Buffer layer 121 is provided on SiC substrate 11 to interpose SiC substrate 11 between buffer layer 121 and base portion 30.

Buffer layer 121 has n type conductivity, and has a thickness of, for example, 0.5 μm. Further, impurity with n type conductivity in buffer layer 121 has a concentration of, for example, 5×10¹⁷ cm⁻³.

Reverse breakdown voltage holding layer 122 is formed on buffer layer 121, and is made of silicon carbide with n type conductivity. For example, reverse breakdown voltage holding layer 122 has a thickness of 10 μm, and includes a conductive impurity of n type at a concentration of 5×10¹⁵ cm⁻³.

Reverse breakdown voltage holding layer 122 has a surface in which the plurality of p regions 123 of p type conductivity are formed with spaces therebetween. In each of p regions 123, an n⁺ region 124 is formed at the surface layer of p region 123. Further, at a location adjacent to n⁺ region 124, a p⁺ region 125 is formed. Oxide film 126 is formed to extend on n⁺ region 124 in one p region 123, p region 123, an exposed portion of reverse breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed.

A maximum value of nitrogen atom concentration is 1×10²¹ cm⁻³ or greater in a region distant away by 10 nm or shorter from an interface between oxide film 126 and each of n+ regions 124, p⁺ regions 125, p regions 123 and reverse breakdown voltage holding layer 122 which serve as semiconductor layers. This achieves improved mobility particularly in a channel region below oxide film 126 (a contact portion of each p region 123 with oxide film 126 between each of n⁺ regions 124 and reverse breakdown voltage holding layer 122).

The following describes a method for manufacturing a semiconductor device 100. It should be noted that FIG. 9-FIG. 12 show steps only in the vicinity of SiC substrate 11 of the plurality of SiC substrates included in substrate group 10, but the same steps are performed also in the vicinity of each of the other SiC substrates.

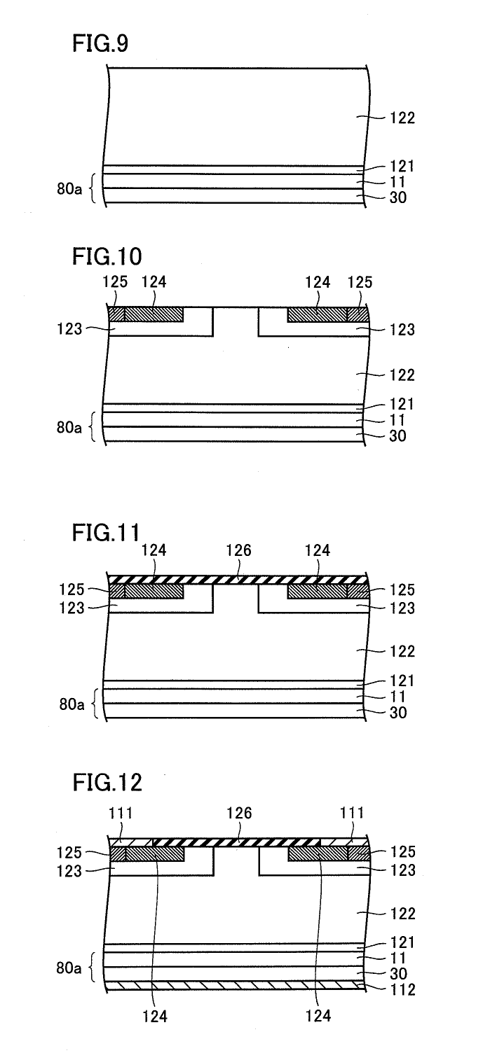

First, in a substrate preparing step (step S110: FIG. 8), silicon carbide substrate 80a (FIG. 1 and FIG. 2) are prepared using the method described in the first or second embodiment. Silicon carbide substrate 80a has n type conductivity.

Referring to FIG. 9, in an epitaxial layer forming step (step S120: FIG. 8), buffer layer 121 and reverse breakdown voltage holding layer 122 are formed as follows.

First, buffer layer 121 is formed on the front-side surface of silicon carbide substrate 80a. Buffer layer 121 is made of silicon carbide of n type conductivity, and is an epitaxial layer having a thickness of 0.5 μm, for example. Buffer layer 121 has a conductive impurity at a concentration of, for example, 5×10¹⁷ cm⁻³.

Next, reverse breakdown voltage holding layer 122 is formed on buffer layer 121. Specifically, a layer made of silicon carbide of n type conductivity is formed using an epitaxial growth method. Reverse breakdown voltage holding layer 122 has a thickness of, for example, 10 μm. Further, reverse breakdown voltage holding layer 122 includes an impurity of n type conductivity at a concentration of, for example, 5×10¹⁵ cm⁻³.

Referring to FIG. 10, an implantation step (step S130: FIG. 8) is performed to form p regions 123, n⁺ regions 124, and p⁺ regions 125 as follows.

First, an impurity of p type conductivity is selectively implanted into portions of reverse breakdown voltage holding layer 122, thereby forming p regions 123. Then, a conductive impurity of n type is selectively implanted into predetermined regions to form n⁺ regions 124, and a conductive impurity of p type is selectively implanted into predetermined regions to form p⁺ regions 125. It should be noted that such selective implantation of the impurities is performed using a mask formed of, for example, an oxide film.

After such an implantation step, an activation annealing process is performed. For example, the annealing is performed in argon atmosphere at a heating temperature of 1700° C. for 30 minutes.

Referring to FIG. 11, a gate insulating film forming step (step S140: FIG. 8) is performed. Specifically, oxide film 126 is formed to cover reverse breakdown voltage holding layer 122, p regions 123, n⁺ regions 124, and p⁺ regions 125. Oxide film 126 may be formed through dry oxidation (thermal oxidation). Conditions for the dry oxidation are, for example, as follows: the heating temperature is 1200° C. and the heating time is 30 minutes.

Thereafter, a nitrogen annealing step (step S150) is performed. Specifically, annealing process is performed in nitrogen monoxide (NO) atmosphere. Conditions for this process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n+ regions 124, and p⁺ regions 125.

It should be noted that after the annealing step using nitrogen monoxide, additional annealing process may be performed using argon (Ar) gas, which is an inert gas. Conditions for this process are, for example, as follows: the heating temperature is 1100° C. and the heating time is 60 minutes.

Referring to FIG. 12, an electrode forming step (step S160: FIG. 8) is performed to form source electrodes 111 and drain electrode 112 in the following manner.

First, a resist film having a pattern is formed on oxide film 126, using a photolithography method. Using the resist film as a mask, portions above n+ regions 124 and p⁺ regions 125 in oxide film 126 are removed by etching. In this way, openings are formed in oxide film 126. Next, in each of the openings, a conductive film is formed in contact with each of n+ regions 124 and p⁺ regions 125. Then, the resist film is removed, thus removing the conductive film's portions located on the resist film (lift-off). This conductive film may be a metal film, for example, may be made of nickel (Ni). As a result of the lift-off, source electrodes 111 are formed.

It should be noted that on this occasion, heat treatment for alloying is preferably performed. For example, the heat treatment is performed in atmosphere of argon (Ar) gas, which is an inert gas, at a heating temperature of 950° C. for two minutes.

Referring to FIG. 7 again, upper source electrodes 127 are formed on source electrodes 111. Further, drain electrode 112 is formed on the backside surface of silicon carbide substrate 80a. In this way, semiconductor device 100 is obtained.

It should be noted that a configuration may be employed in which conductive types are opposite to those in the present embodiment. Namely, a configuration may be employed in which p type and n type are replaced with each other.

Further, the vertical type DiMOSFET has been exemplified, but another semiconductor device may be manufactured using the silicon carbide substrate of the present invention. For example, a RESURF-JFET (Reduced Surface Field-Junction Field Effect Transistor) or a Schottky diode may be manufactured.

(Appendix 1)

A silicon carbide substrate of the present invention is fabricated by the following manufacturing method.

A base portion formed of silicon carbide is prepared. First and second single-crystal substrates each formed of silicon carbide are prepared. The first single-crystal substrate has a first backside surface, a first front-side surface opposite to the first backside surface, and a first side surface connecting the first backside surface and the first front-side surface to each other. The second single-crystal substrate has a second backside surface, a second front-side surface opposite to the second backside surface, and a second side surface connecting the second backside surface and the second front-side surface to each other. A processing chamber is prepared. The processing chamber has an inner surface at least a portion of which is covered with an absorbing portion including Ta atoms and C atoms. The base portion and the first and second single-crystal substrates are disposed in the processing chamber such that each of the first and second backside surfaces faces the base portion and the first and second side surfaces face each other. A temperature in the processing chamber is increased to reach or exceed a temperature at which silicon carbide is able to sublime, so as to connect the first and second side surfaces to each other. When increasing the temperature, at least a portion of the absorbing portion is carbonized.

(Appendix 2)

A semiconductor device of the present invention is fabricated using a silicon carbide substrate fabricated using the following manufacturing method.

A base portion formed of silicon carbide is prepared. First and second single-crystal substrates each formed of silicon carbide are prepared. The first single-crystal substrate has a first backside surface, a first front-side surface opposite to the first backside surface, and a first side surface connecting the first backside surface and the first front-side surface to each other. The second single-crystal substrate has a second backside surface, a second front-side surface opposite to the second backside surface, and a second side surface connecting the second backside surface and the second front-side surface to each other. A processing chamber is prepared. The processing chamber has an inner surface at least a portion of which is covered with an absorbing portion including Ta atoms and C atoms. The base portion and the first and second single-crystal substrates are disposed in the processing chamber such that each of the first and second backside surfaces faces the base portion and the first and second side surfaces face each other. A temperature in the processing chamber is increased to reach or exceed a temperature at which silicon carbide is able to sublime, so as to connect the first and second side surfaces to each other. When increasing the temperature, at least a portion of the absorbing portion is carbonized.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate comprising the steps of:
preparing a base portion formed of silicon carbide;
preparing first and second single-crystal substrates each formed of silicon carbide, said first single-crystal substrate having a first backside surface, a first front-side surface opposite to said first backside surface, and a first side surface connecting said first backside surface and said first front-side surface to each other, said second single-crystal substrate having a second backside surface, a second front-side surface opposite to said second backside surface, and a second side surface connecting said second backside surface and said second front-side surface to each other;
preparing a processing chamber, which has an inner surface at least a portion of which is covered with an absorbing portion including Ta atoms and C atoms;
disposing said base portion and said first and second single-crystal substrates in said processing chamber such that each of said first and second backside surfaces faces said base portion and said first and second side surfaces face each other; and
increasing a temperature in said processing chamber to reach or exceed a temperature at which silicon carbide is able to sublime, so as to connect said first and second side surfaces to each other, in the step of increasing said temperature, at least a portion of said absorbing portion being carbonized.

2. The method for manufacturing the silicon carbide substrate according to claim 1, wherein said absorbing portion has a first portion having Ta atoms at a concentration higher than that of C atoms.

3. The method for manufacturing the silicon carbide substrate according to claim 2, wherein said absorbing portion has a second portion covering said first portion, and a ratio of concentration of Ta atoms to concentration of C atoms in said second portion is smaller than a ratio of the concentration of the Ta atoms to the concentration of the C atoms in said first portion.

4. The method for manufacturing the silicon carbide substrate according to claim 1, wherein in the step of increasing said temperature, each of said first and second single-crystal substrates is set to have a temperature lower than that of said base portion.

5. The method for manufacturing the silicon carbide substrate according to claim 1, wherein in the step of increasing said temperature, each of said first and second backside surfaces and said base portion are connected to each other.

6. The method for manufacturing the silicon carbide substrate according to claim 1, wherein the step of disposing includes a step of placing said first and second single-crystal substrates on said base portion.

7. The method for manufacturing the silicon carbide substrate according to claim 1, wherein at least a portion of said processing chamber is formed of graphite.
